(19) United States
(12) Patent Application Publication
(10) Pub. No.: US 2026/0142645 A1
(43) Pub. Date: May 21, 2026

(54) ACOUSTIC WAVE DEVICE AND METHOD OF MANUFACTURING THE SAME

(71) Applicant: WISOL CO., LTD., Osan-si (KR)

(72) Inventor: Tae Hyun KIM, Osan-si (KR)

(73) Assignee: WISOL CO., LTD., Osan-si (KR)

(21) Appl. No.: 19/378,328

(22) Filed: Nov. 4, 2025

(30) Foreign Application Priority Data
Nov. 21, 2024 (KR) 10-2024-0167390

(51) Int. Cl. H03H 9/17; H03H 3/02

(52) U.S. Cl. CPC H03H 9/173; H03H 3/02; H03H 2003/021

(57) ABSTRACT

The present invention relates to an elastic wave device and a method of manufacturing the same, wherein the elastic wave device according to one embodiment comprises: a piezoelectric substrate having a first surface and a second surface; a support substrate having a third surface adjacent or in contact with the first surface to form a cavity defined by a space; a first adhesive layer disposed between the support substrate and the piezoelectric substrate, forming a bonding interface to join the first surface and the third surface; a second adhesive layer formed on at least one of the third surface and the first surface, which are surfaces where the bonding interface is not formed, the second adhesive layer being exposed within the cavity; and an IDT electrode formed on the second surface, and wherein a thickness of the first adhesive layer is greater than that of the second adhesive layer.

### CROSS-REFERENCES TO RELATED APPLICATION

The present application claims, under 35 U.S.C. § 119(a), the benefit of Korean Patent Application No. 10-2024-0167390, filed on Nov. 21, 2024 which is hereby incorporated by reference in its entirety.

### BACKGROUND

### 1. Field

The present invention relates to filter technology, and more particularly to a bulk acoustic wave device and a method of manufacturing the same.

### 2. Description of the Related Art

Radio frequency (RF) filters are devices that allow some frequencies to pass through and block others, and are used in wireless communication systems, such as cellular base stations, mobile phones, and computing devices. “Pass” means to transmit with relatively low signal loss, while “block” means to transmit with attenuated signal. The frequency range that an RF filter passes through is called the filter's “passband,” and the frequency range that it blocks is called the filter's “cutoff band.” A typical RF filter has at least one passband and at least one blocking band. The specific requirements for the passband or blocking band may vary depending on the specific application. For example, the “passband” may be defined as the frequency range over which the filter's insertion loss is less than a defined value, such as 1 dB, 2 dB, or 3 dB. The “cutoff band” may be defined as the frequency range where the insertion loss of the filter is greater than a defined value, such as 20 dB, 30 dB, 40 dB or more, depending on the application.

The next generation of mobile communications, 6G mobile communications, is being researched and developed, which aims to utilize ultra-high frequency bands and THz frequencies to support faster terabit (Tbps) data transfer rates than conventional mobile communications, and to provide real-time interaction between communications and connected devices with minimal latency (e.g., 0.1 ms latency). Currently, high-performance RF filters for communication systems typically utilize surface acoustic wave (SAW) resonators, bulk acoustic wave (BAW) resonators, and film bulk acoustic wave resonators (FBAR). However, these conventional technologies are not suitable for use in next-generation mobile communications utilizing ultra-high frequency bands and THz frequencies.

Therefore, there is a need for research on an elastic wave device suitable for high bandwidth and high frequency without performance degradation while satisfying the required characteristics of the device through a simple manufacturing process.

### SUMMARY OF THE INVENTION

The technical challenge of the present invention is to provide an elastic wave device suitable for high bandwidth and high frequency without performance degradation while satisfying the required characteristics of the device through a simple manufacturing process.

Furthermore, the technical problem to be solved by the present invention is to provide a manufacturing method for the elastic wave device.

The problems that the present invention is intended to solve are not limited to those mentioned above, and other problems not mentioned will be understood by those skilled in the art from the following description.

According to a first embodiment of the present invention, a piezoelectric substrate having a first surface and a second surface; a support substrate having a third surface adjacent to or in contact with the first surface of the piezoelectric substrate forming a cavity defined as a space; a first adhesive layer disposed between the support substrate and the piezoelectric substrate, forming a bonding interface to join the first surface of the support substrate and the third surface of the piezoelectric substrate; a second adhesive layer formed on at least one of the third surface of the support substrate and the first surface of the piezoelectric substrate, wherein the bonding interface is not formed, and exposed within the cavity; and an elastic wave element comprising an IDT electrode formed on the second surface of the piezoelectric substrate may be provided. A thickness of the first adhesive layer may be greater than a thickness of the second adhesive layer.

According to one embodiment, the first adhesive layer and the second adhesive layer may comprise an inorganic material. The inorganic material may be a metal selected from the group of elements Al, Si, Ti, V, Cr, Fe, Co, Ni, Cu, Zn, Ga, Ge, Zr, Nb, Mo, Ru, Rh, Pd, Ag, In, Sn, Hf, Ta, Pt, Au, W, or an alloy comprising at least one element selected from the group of elements Al, Si, Ti, V, Cr, Fe, Co, Ni, Cu, Zn, Ga, Ge, Zr, Nb, Mo, Ru, Rh, Pd, Ag, In, Sn, Hf, Ta, Pt, Au, W, or an oxide thereof. Preferably, the inorganic material may comprise any one of silicon oxide (SiO₂), titanium oxide (TiO₂), aluminum oxide (Al₂O₃). The second adhesive layer does not have chemical bonds formed by atomic diffusion or atomic rearrangement, and may be shaped in a structure identical to the shape of the cavity.

According to one embodiment, the first adhesive layer may comprise a first sub-adhesive layer deposited on a first surface of the piezoelectric substrate and comprising a first metal atomic layer or a first ceramic atomic layer; a second sub-adhesive layer deposited on a first surface of the support substrate and comprising a second metal atomic layer or a second ceramic atomic layer; and a bonding interface layer having chemical bonds formed by atomic diffusion or atomic rearrangement between the first sub-adhesive layer and the second sub-adhesive layer. The chemical bonds may include at least one of ionic bonds, metallic bonds, covalent bonds, and coordination bonds.

According to one embodiment, all or part of the third surface of the support substrate further comprises a trap-rich layer, wherein the trap-rich layer is disposed between the support substrate and the piezoelectric substrate, and wherein the trap-rich layer may be formed by at least one of polycrystalline silicon, amorphous silicon, or porous silicon.

According to one embodiment, the piezoelectric substrate has a thickness range of 10□ to 500□ and the second adhesive layer has a thickness range of 0.3□ to 10□. The second adhesive layer may have a thickness range of 0.1 □ to 10□The first adhesive layer may be have a range of 1.2 times to 2.0 times the thickness of the second adhesive layer.

The piezoelectric substrate may comprise any one of lithium niobate (LiNbO₃), lithium tantalate, lanthanum gallium silicate, gallium nitride, or aluminum nitride, zinc oxide, or lead zirconate (PZT). The IDT electrode may be aluminum (Al), copper (Cu), platinum (Pt), gold (Au), silver (Ag), titanium (Ti), nickel (Ni), chromium (Cr), molybdenum (Mo), tungsten (W), or an alloy based on any one of these metals. The support substrate may comprise any one of silicon (Si), quartz (Quartz), glass (Glass), silicon carbide (SiC), sapphire, aluminum nitride (AIN).

According to a second embodiment of the invention, the step of preparing a first support substrate having a first surface and having a piezoelectric layer formed on the first surface; preparing a second support substrate having a second surface and having an open cavity on the second surface; providing an atomic layer on an exposed surface of the piezoelectric layer formed on the first surface of the first support substrate and on a second surface of the second support substrate, respectively; pressing or overlapping the exposed surface of the piezoelectric layer and the second surface of the second support substrate to form an adhesive layer so that the open cavity of the second support substrate is closed to form a space; removing the first support substrate so that a other surface opposite to the exposed surface of the piezoelectric layer is exposed; and forming an IDT electrode on the other surface of the exposed piezoelectric layer, a method of manufacturing an elastic wave device may be provided.

According to one embodiment, the step of forming an atomic layer on an exposed surface of the piezoelectric layer formed on a first surface of the first support substrate and a second surface of the second support substrate, respectively, may comprise depositing an inorganic material on at least one of the exposed surface of the piezoelectric layer and the second surface of the second support substrate.

According to one embodiment, the step of forming the adhesive layer by closely pressing the exposed surface of the piezoelectric layer and the second surface of the second support substrate so that the open cavity of the second substrate is closed to form a space may include the step of forming a bonding interface layer through atomic diffusion between the first atomic layer and the second atomic layer. The step of forming the atomic layer and the step of forming the adhesive layer by closely pressing the exposed surface of the piezoelectric layer and the second surface of the second support substrate may be performed in a vacuum.

According to one embodiment, the step of preparing the second support substrate may further comprise the step of forming a trap-rich layer on all or part of the second surface of the second support substrate. The step of preparing the first support substrate may further comprise the step of forming a dielectric layer between the first support substrate and the piezoelectric layer. The space formed by closing the open cavity of the second support substrate may be under vacuum.

In the elastic wave device according to one embodiment of the present invention, a first surface of the piezoelectric substrate is not exposed through the cavity by forming a sealed cavity formed between the support substrate and the piezoelectric substrate, which may block impurities from entering the first surface of the piezoelectric substrate, and a first surface of the piezoelectric substrate adjacent to the cavity may be protected by an adhesive layer disposed thereon.

Furthermore, the elastic wave device according to other embodiments of the present invention may improve the insertion loss and distortion (linearity) of the RF scene by adding a trap rich layer or trap rich region between the support substrate and the piezoelectric substrate.

Furthermore, a manufacturing method of an elastic wave device according to another embodiment of the present invention may manufacture an elastic wave device simply and at low cost by bonding a support substrate having a cavity and a piezoelectric substrate, without the need for a complex and precise etching process that requires forming an etching hole and removing a sacrificial layer corresponding to the cavity through the etching hole.

Furthermore, by performing the bonding process using the bonding material in a vacuum, the cavity may be maintained in a vacuum state, which may improve the degradation of the piezoelectric layer caused by impurities or foreign matter.

However, the effects of the present invention are not limited to the above effects, and may be expanded in various ways without departing from the technical ideas and scope of the present invention.

### BRIEF DESCRIPTION OF THE DRAWINGS

FIG. 1A is a partially exploded perspective view of an elastic wave element according to a first embodiment of the present invention.

FIG. 1B is a cross-sectional view of an elastic wave device according to a first embodiment of the present invention.

FIGS. 2A and 2B are cross-sectional views of an elastic wave element according to a second embodiment of the present invention.

FIGS. 3A to 3E are drawings to illustrate a method of fabricating an elastic wave device according to a first embodiment of the present invention.

FIGS. 4A to 4E are drawings for illustrating a manufacturing method of an elastic wave device according to a second embodiment of the present invention.

FIGS. 5A and 5B are drawings for illustrating the effect of a manufacturing method of an elastic wave device according to an embodiment of the present invention.

### DETAILED DESCRIPTION

Hereinafter, embodiments of the present invention will be described in detail with reference to the accompanying drawings.

The embodiments of the invention to be described hereinafter are provided for the purpose of explaining the invention more clearly to those having ordinary knowledge in the art, and the scope of the invention is not limited by the following embodiments, and the following embodiments may be modified in various other forms.

The terms used in this disclosure are intended to describe specific embodiments and are not intended to limit the invention of. Terms used herein in the singular form may include the plural form, unless the context clearly indicates otherwise. Furthermore, the terms “comprise” and/or “comprising” as used herein are intended to specify the presence of the mentioned shapes, steps, numbers, motions, absences, elements, and/or groups thereof, and are not intended to exclude the presence or addition of one or more other shapes, steps, numbers, motions, absences, elements, and/or groups thereof. Furthermore, as used herein, the term “connected” is intended to mean not only that certain elements are directly connected, but also that they are indirectly connected by the interposition of other elements between them.

Further, when the present disclosure refers to a member being located “on” another member, this includes not only when a member is abutting another member, but also when there is another member between the two members. As used herein, the term “and/or” includes any one of the enumerated items and any combination of one or more of them. In addition, the terms “about,” “substantially,” and the like as used in the disclosure are intended to mean at or near the range of values or degrees, taking into account inherent manufacturing and material tolerances, and to prevent infringers from taking unfair advantage of the disclosure where precise or absolute figures are given for the purpose of illustration.

Embodiments of the present invention will now be described in detail with reference to the accompanying drawings. The sizes or thicknesses of the areas or parts shown in the accompanying drawings may be somewhat exaggerated for clarity and ease of description. Throughout the detailed description, like reference numerals designate like components.

Recently, transversely excited film bulk acoustic resonators (laterally excited bulk wave resonator (XBAR)) suitable for high bandwidth and high frequency have been researched and developed. The XBAR includes an interdigital transducer (IDT) formed on a thin floating layer or diaphragm of piezoelectric material. A microwave signal applied to the IDT excites a shear fundamental acoustic wave within the piezoelectric diaphragm such that the acoustic energy flows in a direction orthogonal to or transverse to the direction of the electric field generated by the IDT, i.e., substantially perpendicular to the surface of the layer. The XBAR may also provide very high electromechanical coupling and high frequency capability above conventional resonance.

The resonant frequency of such an XBAR may be determined by the thickness of a piezoelectric diaphragm suspended above the cavity. One surface of the piezoelectric diaphragm may be exposed or closed by the cavity. Specifically, if a first surface of the piezoelectric diaphragm is exposed by cavity, a piezoelectric layer may be formed on a first surface of a support substrate and then an open cavity may be formed on the other surface of the support substrate by an etching process, or a open cavity may be first formed on a first surface of the support substrate by an etching process and then a piezoelectric layer may be disposed on a base substrate having the open cavity. If a first surface of the piezoelectric diaphragm is closed by a cavity, a closed cavity may be formed between the support substrate and the piezoelectric layer by forming a piezoelectric layer on a first surface of a support substrate on which a sacrificial layer is deposited, and then forming an etching hole and removing the sacrificial layer of the support substrate through the etching hole.

However, in a structure in which one surface of the piezoelectric diaphragm is exposed by a cavity, impurities may be introduced into the exposed surface of the piezoelectric diaphragm, which may cause the performance of the filter to be reduced or damage to the piezoelectric diaphragm through the exposed surface.

In addition, in a structure in which one surface of the piezoelectric diaphragm is closed by a cavity, it is necessary to form a piezoelectric layer on a support substrate, and then form etching holes on the support substrate and the piezoelectric layer, and etch a sacrificial layer of the support substrate through the formed etching holes to form the cavity, which is complicated and requires precision in etching, and a part of the piezoelectric layer may also be etched together with the sacrificial layer. In this case, the resonant frequency of the resonator is determined by the thickness of the piezoelectric diaphragm, and it may be difficult to satisfy the required characteristics of the resonator.

Therefore, there is a need for the development of an elastic wave device suitable for high bandwidth and high frequency without performance degradation while satisfying the required characteristics of the device through a simple manufacturing process.

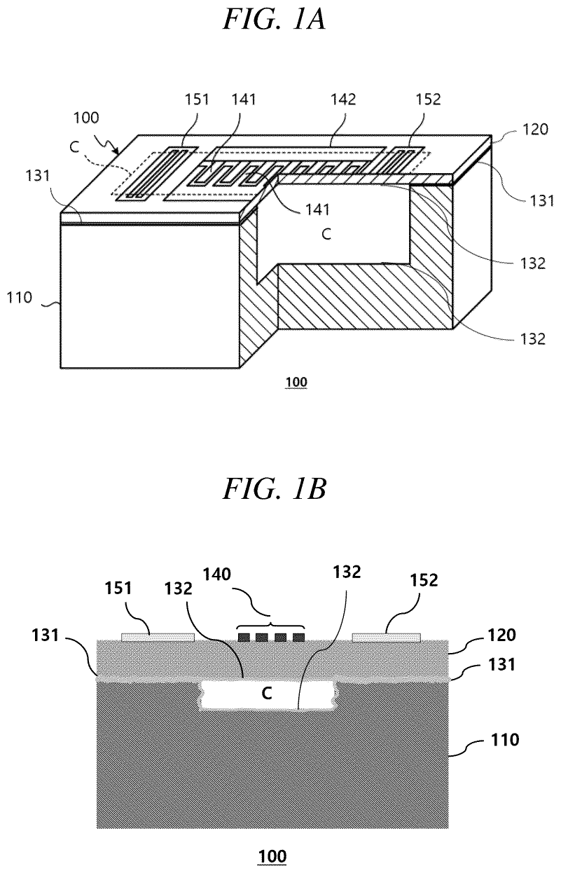

FIG. 1A is a partially exploded perspective view of an elastic wave device according to a first embodiment of the present invention, and FIG. 1B is a cross-sectional view of an elastic wave device 100.

Referring to FIGS. 1A and 1B, the elastic wave device 100 may comprise a support substrate 110, a piezoelectric substrate 120, an adhesive layer 130, and an IDT electrode 140. The IDT electrodes 140 may include finger electrodes 141 and busbar electrodes 142.

The piezoelectric substrate 120 may have a first surface and a second surface, and may preferably be composed of lithium niobate (LiNbO₃). However, the material of the piezoelectric substrate 120 is not limited to the above, and may be, for example, lithium tantalate, lanthanum gallium silicate, gallium nitride, or aluminum nitride, zinc oxide, or lead titanate (PZT). The thickness of the piezoelectric substrate 120 bonded to one surface of the support substrate 110 may range from 10 nm to 500 nm. If the piezoelectric substrate 120 is 10 nm or less thick, it may be difficult to handle during the manufacturing process and may break easily, and if it is 500 nm or more thick, it may be difficult to implement a filter that operates in the desired high and high frequency bands. The support substrate 110 also has a smaller coefficient of thermal expansion than the piezoelectric substrate 120. By attaching the support substrate 110, which has a smaller coefficient of thermal expansion than the piezoelectric substrate 120, to the piezoelectric substrate 120, the change in the size of the piezoelectric substrate 120 when the temperature changes may be suppressed, thereby suppressing the change in the frequency characteristics of the elastic wave element 100. Also, preferably, the piezoelectric substrate 120 may be a single crystal layer.

The support substrate 110 is a substrate that supports the piezoelectric substrate 120 and has a third surface adjacent or in contact with the first surface of the piezoelectric substrate 120 to form a cavity defined by the space. The support substrate 110 may be a non-limiting example of silicon, quartz, glass, silicon carbide (SiC), sapphire, aluminum nitride (AIN), or any other material. For example, the support substrate 110 may have a silicon thermal oxide (TOX) layer and a crystalline silicon layer.

The adhesive layer 130 includes a first adhesive layer 131 and a second adhesive layer 132, which may be disposed between the support substrate 110 and the piezoelectric substrate 120 to bond them. The first adhesive layer 131 may form a bonding interface such that the third surface of the support substrate 110 and the first surface of the piezoelectric substrate 120 are bonded. The second adhesive layer 132 may be defined as a region where the bonding interface is not formed, where the third surface of the support substrate 110 and the first surface of the piezoelectric substrate 120 are not bonded by the cavity C. Such a second adhesive layer 132 may be present on at least one of the third surface of the support substrate 110 and the first surface of the piezoelectric substrate 120, and may be exposed to the cavity C. The thickness of the first adhesive layer 131 may be thicker than the thickness of the second adhesive layer 132.

In the manufacturing method of the elastic wave device 100 to be described later, a sub-adhesive layer is formed on the third surface of the support substrate 110 and the first surface of the piezoelectric substrate 120, respectively, and then the two surfaces of the support substrate 110 and the piezoelectric substrate 120 are bonded, a bonding interface is formed through the sub-adhesive layer of the support substrate 110 and the sub-adhesive layer of the piezoelectric substrate 120 in a region where the two surfaces of the support substrate 110 and the piezoelectric substrate 120 are in contact, and in a region where the two surfaces of the support substrate 110 and the piezoelectric substrate 120 are not in contact, the adhesive layers in the support substrate 110 or the piezoelectric substrate 120 remain independent. Thus, the thickness of the first adhesive layer 131 forming the bonding interface may be greater than or equal to the thickness of at least the second adhesive layer 132.

In one embodiment, the first adhesive layer 131 and the second adhesive layer 132 comprise an inorganic material, wherein the inorganic material may comprise a ceramic material based on an oxide or silicate or a metallic material, and more specifically, the inorganic material may comprise Al, Si, Ti, V, Cr, Fe, Co, Ni, Cu, Zn, Ga, Ge, Zr, Nb, Mo, Ru, Rh, Pd, Ag, In, Sn, Hf, Ta, Pt, Au, W, or a metal selected from the group of elements of Al, Ti, V, Cr, Fe, Co, Ni, Cu, Zn, Ga, Ge, Zr, Nb, Mo, Ru, Rh, Pd, Ag, In, Sn, Hf, Ta, Pt, Au, W, or an alloy comprising at least one element selected from the group of elements, or an oxide thereof. Preferably, the inorganic material may comprise any one of silicon oxide (SiO₂), titanium oxide (TiO₂), aluminum oxide (Al₂O₃).

The second adhesive layer 132 may have a thickness in the range of 0.3□ to 10□ and may be shaped with the same structure as the shape of the cavity C. Specifically, the second adhesive layer 132 may cover the shape of the cavity C. The second adhesive layer 132 may have a stable bonding strength within a thickness range of 0.3□ to 10□ and is advantageous from a manufacturing cost perspective. Furthermore, the thickness of the first adhesive layer 131 has a range of 1.2 times to 2.0 times the thickness of the second adhesive layer 132.

In one embodiment, the first adhesive layer comprises a first sub-adhesive layer deposited on a first surface of the piezoelectric substrate 120 and comprising a first metal atomic layer or a first ceramic atomic layer, a second sub-adhesive layer deposited on a first surface of the support substrate 110 and comprising a second metal atomic layer or a second ceramic atomic layer, and a bonding interface layer between the metal atomic layers between the first sub-adhesive layer and the second sub-adhesive layer, a bonding interface layer formed by atomic diffusion or atomic rearrangement between the ceramic atomic layers or between the metal atomic layer and the ceramic atomic layer. The bonding interfacial layer has chemical bonds and has a strong atomic diffusion bond between the piezoelectric substrate 120 and the support substrate 110 by the chemical bonds. The chemical bonds may include at least one of ionic bonds, metallic bonds, covalent bonds, and coordination bonds.

In the above atomic diffusion bonding, by superimposing two substrates, each having an atomic layer deposited thereon, under the same vacuum or under the same atmospheric pressure conditions, a bonding involving atomic diffusion and atomic rearrangement at the bonding interface becomes possible. Although metal atoms in the solid phase may hardly move at room temperature, in the above atomic diffusion bonding, the bonding is achieved by using the large surface energy of the bonding layer deposited in the vacuum chamber as the driving force for the bonding, and by moving the atoms of the materials comprising the bonding layer at room temperature using the large atomic diffusion performance on the surface of the bonding layer and the atomic rearrangement phenomenon at the contact interface. This surface atomic diffusion or atomic rearrangement phenomenon is a phenomenon in which defects (vacancies) of atoms on the surface and at the bonding interface move at high speeds even at low energies, and may be utilized to move metal atoms at room temperature. In the above atomic diffusion bonding, bonding at room temperature using a bonding layer of any metal is possible, but in particular, the larger the magnetic diffusion coefficient of atoms in metal materials such as Ti and Au, the more active the movement of atoms at the bonding interface and the easier it is for atomic rearrangement to occur, resulting in high bonding performance.

The metal atomic layer or the ceramic atomic layer may be deposited on the support substrate 110 and the piezoelectric substrate 120 via any one of Atomic Layer Deposition (ALD), Chemical Vapor Deposition (CVD), Plasma Enhanced CVD (PECVD), and Physical Vapor Deposition (PVD), respectively. Preferably, the metal atomic layer or the ceramic atomic layer may be deposited by PVD. The thickness and type of the metal atomic layer or the ceramic atomic layer deposited on the support substrate 110 and the piezoelectric substrate 120, respectively, may be the same or different. Specifically, since the thickness of the piezoelectric substrate 120 is relatively much smaller than the thickness of the support substrate 110, the thickness of the atomic layer deposited on the piezoelectric substrate 120 is preferably larger than the thickness of the atomic layer deposited on the support substrate 110, so that the stability of the piezoelectric substrate 120 may be increased.

In another embodiment, the first adhesive layer may comprise a first sub-adhesive layer bonded to the piezoelectric substrate 120, a second sub-adhesive layer bonded to the support substrate 110, and an amorphous layer between the first sub-adhesive layer and the second sub-adhesive layer. The first sub-adhesive layer and the second sub-adhesive layer have a composition of Si₁₋ₓOₓ(0.01≤x≤0.5). Here, the oxygen ratio of the amorphous layer may be higher than the oxygen ratio of the first sub-adhesive layer or the second sub-adhesive layer. It is believed that oxygen diffusion from the sub-adhesive layer of the support substrate 110 or the piezoelectric substrate 120 to the amorphous layer occurs, resulting in a higher ratio of oxygen in the amorphous layer created between them than the ratio of oxygen in the sub-adhesive layer. Furthermore, in the case of oxygen diffusion, the bonding strength between the support substrate 110 and the piezoelectric substrate 120 is increased, and delamination of the piezoelectric substrate 120 is less likely to occur. Furthermore, the stacked structure of the amorphous layer between the first sub-adhesive layer and the second sub-adhesive layer may serve as a trap-rich layer to be described later, which increases the insulation of the bonding layer to inhibit the transfer of electrons from the support substrate 110 to the piezoelectric substrate 120.

An IDT electrode 140 may be disposed on the second surface of the piezoelectric substrate 120. A plurality of finger electrodes 141 of the IDT electrode 140 may extend spaced apart from each other in the orthogonal direction of the field direction (X-axis direction), and a one end of the finger electrodes 141 may be connected to a busbar electrode 142 to form a comb pattern. The finger electrodes 141 may be aluminum, copper, platinum, Pt, Au, silver, Ag, titanium, Ni, nickel, chromium, Cr, molybdenum, Mo, tungsten, W, or an alloy based on any of these metals. The upper finger electrode 141 and the lower finger electrode 141 may be disposed intersecting each other. The finger electrodes 141 may further include an offset electrode (not shown) that is orthogonal to the other end of the finger electrodes 141 and thus opposed. The finger electrode 141 is connected to the busbar electrode 142 at the top and the offset electrode (not shown) is connected to the busbar electrode 142 at the bottom and disposed opposite each other. The offset electrodes may have a range that is smaller than the length of the finger electrodes 141.

The intersection region between the finger electrodes and the intersection region between the offset electrodes and the region corresponding to the thickness of the busbar electrode may have different field velocities. Non-limitingly, the reflectors 151, 152 may be disposed at each end of the IDT electrode 140, i.e., the IDT electrode 140 may be disposed between the reflectors 151 and 152. The reflectors 151, 152 may be designed to have a high reflection coefficient in a defined band including the resonant frequency of the elastic wave element 100 to prevent the reflected elastic wave from propagating outwardly. The thickness of the IDT electrodes 140 may vary depending on the type of metal, and the width of the IDT electrodes 140 may be determined based on the performance of the filter required.

As described above, by forming a cavity formed between the support substrate 110 and the piezoelectric substrate 120, a first surface of the piezoelectric substrate 120 is not exposed through the cavity, which may block impurities from entering the first surface of the piezoelectric substrate 120. Furthermore, the first surface of the piezoelectric substrate 120 adjacent to the cavity may be disposed with an adhesive layer, which may serve as a protective layer. The shape of the cavity C may be realized in various shapes, including rectangular and the like.

Turning to the operation of the elastic wave device 100 of the present invention, when an RF signal is applied to the IDT electrodes 140, the RF signal may generate a time-varying electric field between the finger electrodes 141. The direction of the electric field may be in the x-direction, or in a direction parallel to the surface of the piezoelectric substrate 120. Due to the high dielectric constant of the piezoelectric substrate, the electric field may be highly concentrated and distributed within the piezoelectric substrate compared to air. The electric field in the x-direction may cause shear deformation. Thus, it may strongly excite the fundamental shear acoustic mode within the piezoelectric substrate 120. In the present invention, “shear deformation” is defined as a deformation in which, during deformation, parallel faces within a material remain parallel to each other and maintain a constant distance apart. “Shear acoustic mode” is defined as a mode of acoustic vibration of a medium that causes shear deformation of the medium. Although the atomic motion due to shear deformation of the elastic wave element 100 is mostly in the x-direction, the direction of acoustic energy flow of the excited fundamental shear acoustic mode may be in the thickness direction of the piezoelectric substrate 120.

Acoustic resonators based on shear acoustic wave resonance may achieve better performance than current state-of-the-art Film-Bulk-Acoustic-Resonator (FBAR) and Solidly-Mounted-Resonator Bulk-Acoustic-Wave (SMR BAW) devices, where the electric field is applied in the thickness direction. In these resonators, the acoustic modes are compressed into thickness-directed atomic motions so that the direction of acoustic energy flow is in the thickness direction. Furthermore, the piezoelectric coupling for resonance in shear-wave transversely excited film bulk acoustic resonators may be higher (>20%) compared to other acoustic resonators. The high piezoelectric coupling enables the design and implementation of microwave and millimeter-wave filters with significant bandwidth.

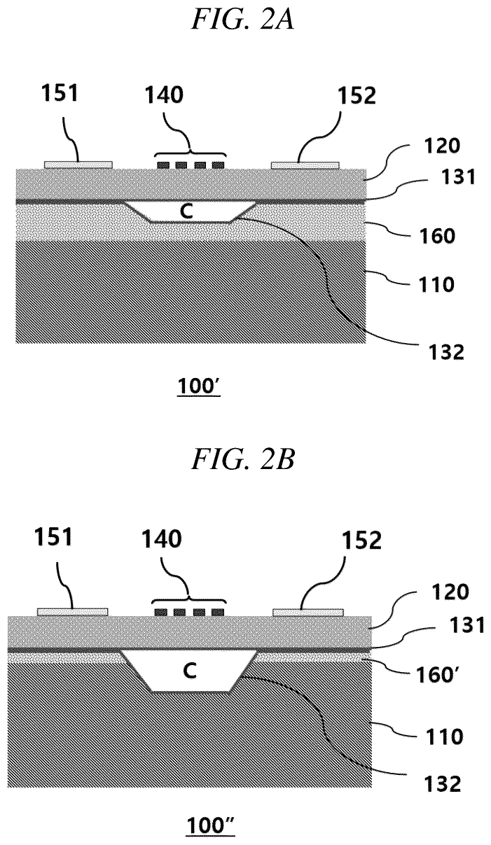

On the other hand, even if the support substrate 110 has a high resistivity, it may contain free charge carriers, which may affect the performance of the device by increasing the insertion loss and distortion (linearity) of the RF signal, especially with respect to the solid piezoelectric substrate 120. To improve this, variants of the present invention may further include a trap rich layer or trap rich region between the support substrate 110 and the piezoelectric substrate 120, as shown in FIGS. 2A and 2B.

Trap rich layers may be formed within a silicon substrate by irradiating the surface of the substrate with neutrons, protons, or various ions (silicon, argon, nitrogen, neon gas, oxygen, etc.) that create defects within the crystal structure of the substrate. Alternatively, trap rich regions may be formed within a silicon substrate by introducing deep trap impurities, such as gold, copper, or other metal ions. Such impurities may be formed by ion implantation, diffusion, or several other methods. The trap rich regions may be formed by a combination of these techniques.

FIGS. 2A and 2B are cross-sectional views of an elastic wave element according to a second embodiment of the present invention.

Referring to FIGS. 2A and 2B, the elastic wave devices 100′, 100″ may comprise a support substrate 110, a piezoelectric substrate 120, an adhesive layer 130, and IDT electrodes 140. The IDT electrodes 140 may include finger electrodes 141 and busbar electrodes 142. Since the support substrate 110, piezoelectric substrate 120, adhesive layer 130, and IDT electrode 140 of the elastic wave device 100′, 100″ are similar to the support substrate 110, piezoelectric substrate 120, adhesive layer 130, and IDT electrode 140 of the elastic wave device 100 described in FIGS. 1A and 1B, the description of the elastic wave device 100′, 100″ may refer to the description of FIGS. 1A and 1B unless contradictory.

Referring to FIG. 2A, a trap rich layer 160 may be further disposed covering an entire first surface of the support substrate 110. Furthermore, the cavity C may be accommodated within the trap rich layer 160 if the trap rich layer 160 has a sufficient thickness to accommodate the cavity C.

Referring to FIG. 2B, a trap rich layer 160′ covering a portion of one surface of the support substrate 110 may be further disposed. In the case of FIG. 2b, the trap rich layer 160′ may not be disposed on a portion of the support substrate 110 that is exposed by the cavity (C) of the piezoelectric substrate 120, but may be disposed on a region where the two surfaces of the support substrate 110 and the piezoelectric substrate 120 are joined. FIG. 2b illustrates that the cavity C may be formed within the support substrate 110 if the trap rich layer 160′ has a thin thickness that might not accommodate the cavity C.

The trap-rich layers 160, 160′ may electrically isolate the support substrate 110 from the piezoelectric substrate 120 to improve performance (e.g., linearity and spurious suppression). The term “trap-rich” refers to a layer that may absorb charge without forming a conductive layer. The trap-rich layer may be formed by at least one of a polycrystalline material, an amorphous material, or a porous material, such as polycrystalline silicon, amorphous silicon, or porous silicon, but the present invention is not limited to these materials. Also non-limitingly, the trap rich layers 160, 160′ may be formed by ion implantation into the surface layer of the support substrate 110 or by etching and structuring of the surface layer of the support substrate 100.

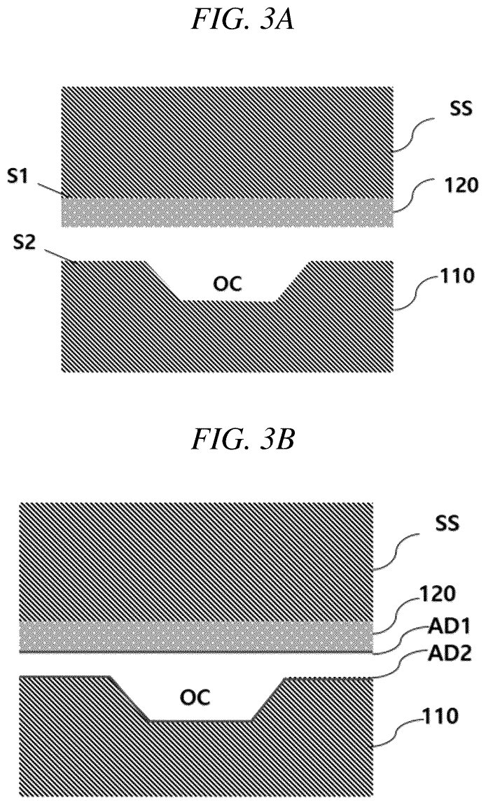

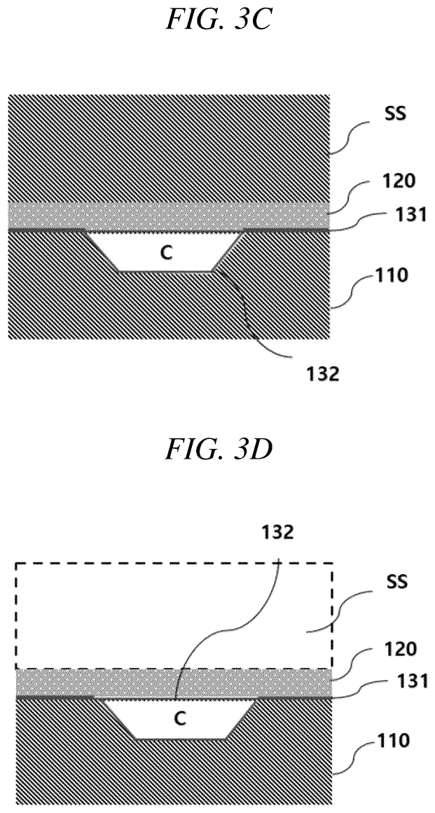

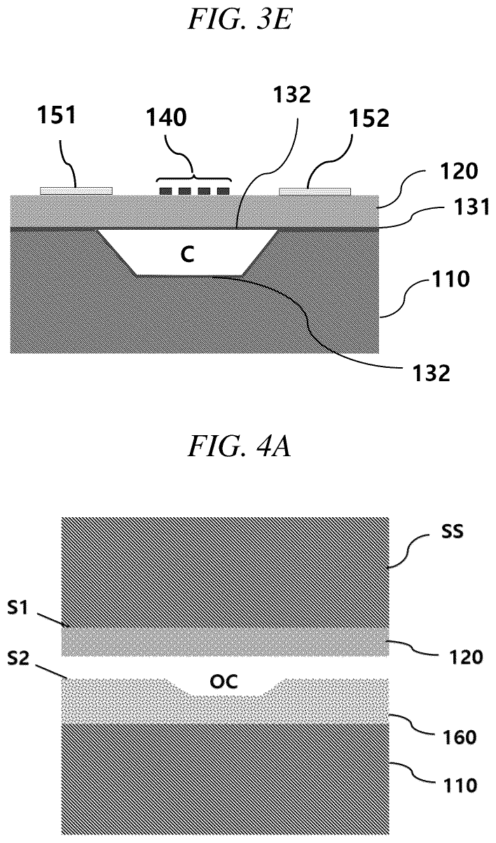

FIGS. 3A through 3E are drawings to illustrate a method of fabricating an elastic wave element according to a first embodiment of the present invention.

First, a first support substrate (SS) having a first surface (S1) and a piezoelectric layer (120) formed on the first surface (S1) may be prepared, as shown in FIG. 3A. The first support substrate SS may be, by way of non-limiting example, silicon, sapphire, AIN, crystal, SiC, or any other material. The piezoelectric layer 120 may include any one of lithium niobate (LiNbO₃), lithium tantalate, lanthanum gallium silicate, gallium nitride, or aluminum nitride, zinc oxide, or lead titanate (PZT). A second support substrate 110 having a second surface S2 and an open cavity on the second surface may be further prepared. The step of preparing the second support substrate 110 having the open cavity OC may include forming the open cavity OC on the second support substrate 110 via a photolithography process and an etching process. The second support substrate 110 may be the same material as the first support substrate SS.

Next, as shown in FIG. 3B, sub-adhesive layers AD1, AD2 are deposited on a first surface S1 of the piezoelectric layer 120 formed on the first support substrate SS and a first surface S2 of the second support substrate 110, respectively.

The first sub-adhesive layer AD1 is deposited on a first surface of the piezoelectric substrate 120 by a corresponding deposition method and comprises a first metal atomic layer or a first ceramic atomic layer. The second sub-adhesive layer AD2 is deposited on one surface of the support substrate 110 by a corresponding deposition method and may comprise a second metal atomic layer or a second ceramic atomic layer. The deposition method may include any one of Atomic Layer Deposition (ALD), Chemical Vapor Deposition (CVD), Plasma Enhanced CVD (PECVD), and Physical Vapor Deposition (PVD). Preferably, the metal atomic layer or the ceramic atomic layer may be deposited by a PVD method.

Furthermore, the first sub-adhesive layer (AD1) and the second sub-adhesive layer (AD2) are preferably deposited under high vacuum so that they have an active state (activation) in which chemical bonds between atoms may be easily formed at the bonding surface. However, it is not necessarily limited thereto, and the first sub-adhesive layer AD1 and the second sub-adhesive layer AD2 may also be deposited at atmospheric pressure if the first sub-adhesive layer AD1 and the second sub-adhesive layer AD2 have an active state even at atmospheric pressure. The active first sub-adhesive layer AD1 and the second sub-adhesive layer AD2 have a high self-diffusion coefficient, so that bonding and diffusion by atomic rearrangement may easily occur.

The first adhesive layer 131 and the second adhesive layer 132 comprise an inorganic material, the inorganic material may comprise a ceramic material based on oxides or silicates or a metallic material, and more particularly the inorganic material may comprise Al, Si, Ti, V, Cr, Fe, Co, Ni, Cu, Zn, Ga, Ge, Zr, Nb, Mo, Ru, Rh, Pd, Ag, In, Sn, Hf, Ta, Pt, Au, W, or a metal selected from the group of elements of Al, Ti, V, Cr, Fe, Co, Ni, Cu, Zn, Ga, Ge, Zr, Nb, Mo, Ru, Rh, Pd, Ag, In, Sn, Hf, Ta, Pt, Au, W, or an alloy comprising at least one element selected from the group of elements, or an oxide thereof.

Subsequently, as shown in FIG. 3C, the exposed surface of the piezoelectric layer 120 and the second surface S2 of the second support substrate 110 may be pressed or overlapped to form adhesive layers 131, 132 such that the open cavity OC of the second support substrate 110 is closed to form an enclosed space C. Within the adhesive layer 131, chemical or metallic bonding may occur due to atomic diffusion and recombination between the first sub-adhesive layer AD1 and the second sub-adhesive layer AD2. For example, atomic diffusion and recombination may occur as atoms of the first sub-adhesive layer AD1 migrate to the second sub-adhesive layer AD2 or as atoms of the second sub-adhesive layer AD2 migrate to the first sub-adhesive layer AD1, and the piezoelectric layer 120 and the second support substrate 110 may be strongly bonded by the chemical bonds formed by the atomic diffusion and recombination. Furthermore, in the adhesive layer 132, the first sub-adhesive layer AD1 and the second sub-adhesive layer AD2 are not contacted by the cavity C, so that chemical bonds formed by atomic diffusion and recombination such as the adhesive layer 131 may not occur. As a result, the adhesive layer 132 may not include a bonding interface by chemical bonding.

The second adhesive layer 132 may have a thickness in the range of 0.3□ to 10□, and may have a stable bond strength within this thickness range, which is advantageous from a manufacturing cost perspective. The thickness of the second adhesive layer 132 may be smaller than the thickness of the first adhesive layer 131.

In another embodiment, sub-adhesive layers are formed on a first surface of the piezoelectric layer 120 and a first surface of the second support substrate 110, respectively, and a neutralizing beam may be irradiated on a surface of the first sub-adhesive layer formed on a first surface of the piezoelectric layer 120 and a surface of the second sub-adhesive layer formed on a first surface of the second support substrate 110 to activate the first sub-adhesive layer and the second sub-adhesive layer. Then, by directly contacting the activated first sub-adhesive layer and the activated second sub-adhesive layer, and applying pressure, the adhesive layers 131, 132 may be obtained. An amorphous layer may be formed between the activated first sub-adhesive layer and the activated second sub-adhesive layer. Further, by introducing oxygen gas, the voltage force and oxygen partial pressure of the atmosphere in the chamber may be changed by changing the amount of oxygen gas introduced, and the oxygen ratio X of the first sub-adhesive layer and the second sub-adhesive layer may be adjusted thereby.

Subsequently, as shown in FIG. 3D, the first support substrate SS may be removed to expose the other surface of the piezoelectric layer 120 opposite the first surface S3 of the piezoelectric layer 120 in contact with the adhesive layers 131, 132. The first support substrate SS may be removed via a polishing process or an etching process. Subsequently, the IDT electrodes 140 and reflectors 151, 152 may be formed on the other surface S4 of the exposed piezoelectric layer 120, as shown in FIG. 3E.

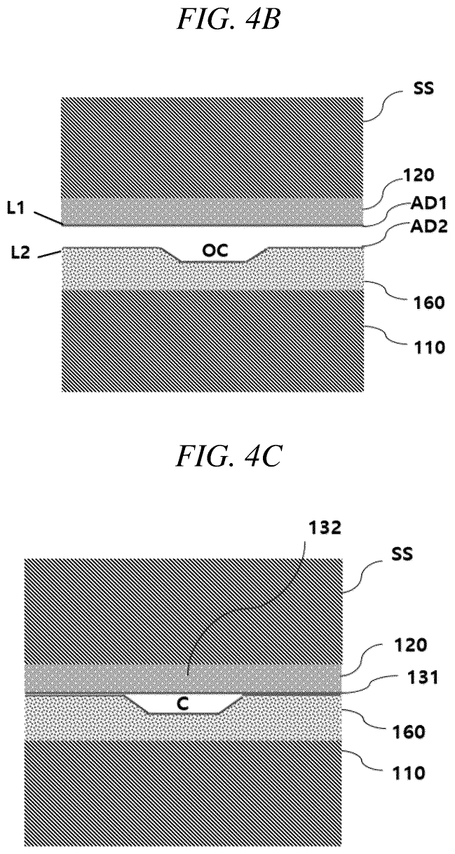

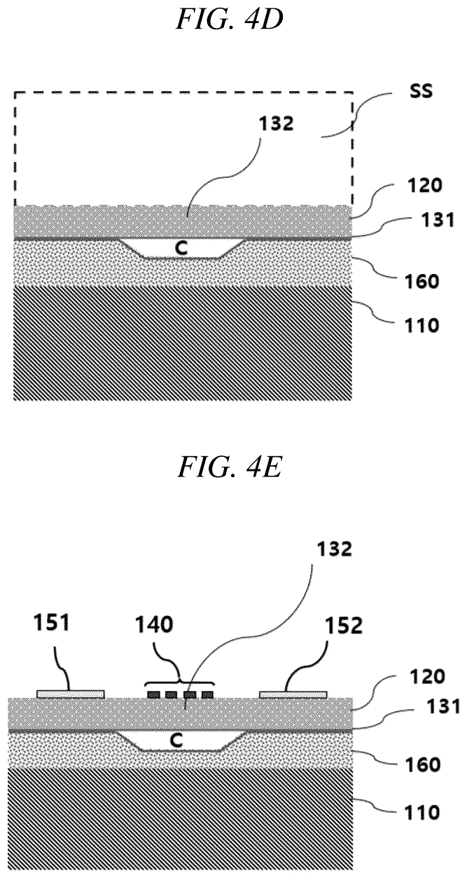

FIGS. 4A to 4E are drawings to illustrate a method of fabricating an elastic wave element according to a second embodiment of the present invention.

First, as shown in FIG. 4A, a first support substrate SS2 having a first surface S1 and a piezoelectric layer 120 formed on the first surface S1 may be prepared. The first support substrate SS2 and the piezoelectric layer 120 are similar to the first support substrate SS and the piezoelectric layer 120 of FIG. 3a, so reference may be made to the description of the first support substrate SS and the piezoelectric layer 120 of FIG. 3A. The step of preparing the first support substrate SS2 on which the piezoelectric layer 120 is formed may include forming the piezoelectric layer 120 on the first support substrate SS via a film process or a deposition process. Optionally, a dielectric layer (e.g., SiO₂) (not shown) may be further formed between the first support substrate SS2 and the piezoelectric layer 120.

The second support substrate 110 having a second surface S2 and having a trap-rich layer 160 having an open cavity on the second surface may be further prepared. The step of preparing the second support substrate 110 may include forming the trap-rich layer 160 on the second support substrate 110 via a deposition process or a film process, and forming the open cavities (OCs) in the trap-rich layer 160 via a photolithography process and an etching process. The second support substrate 110 may be the same material as the first support substrate SS2. The trap-rich layer 160′ may electrically isolate the support substrate 110 from the piezoelectric substrate 120 to improve performance (e.g., linearity and spurious suppression, etc.).

Next, as shown in FIG. 4B, sub-adhesive layers AD1, AD2 are deposited on one surface of the piezoelectric layer 120 formed on the first support substrate SS2 and on one surface of the trap-rich layer 160 formed on the second support substrate 110, respectively.

The first sub-adhesive layer AD1 is deposited on a first surface of the piezoelectric substrate 120 by a corresponding deposition method and comprises a first metal atomic layer or a first ceramic atomic layer. The second sub-adhesive layer AD2 is deposited on a first surface of the support substrate 110 by a corresponding deposition method and may comprise a second metal atomic layer or a second ceramic atomic layer. The first sub-adhesive layer AD1 and the second sub-adhesive layer AD2 are preferably deposited in a high vacuum state so that they have an active state (activation) in which chemical bonds or metal bonds between atoms may be easily formed at the bonding surface. In the active state, the first sub-adhesive layer AD1 and the second sub-adhesive layer AD2 may easily undergo bonding and diffusion by atomic rearrangement due to the self-diffusion coefficient.

The first adhesive layer 131 and the second adhesive layer 132 comprise an inorganic material, the inorganic material may comprise a ceramic material based on oxides or silicates or a metallic material, and more particularly the inorganic material may comprise Al, Si, Ti, V, Cr, Fe, Co, Ni, Cu, Zn, Ga, Ge, Zr, Nb, Mo, Ru, Rh, Pd, Ag, In, Sn, Hf, Ta, Pt, Au, W, or a metal selected from the group of elements, or an alloy comprising at least one element selected from the group of elements, or an oxide thereof. Preferably, the inorganic material may comprise any one of silicon oxide (SiO₂), titanium oxide (TiO₂), aluminum oxide (Al₂O₃), or alloys thereof.

Then, as shown in FIG. 4C, the exposed surface L1 of the piezoelectric layer 120 and the exposed surface L2 of the trap rich layer 160 may be closely adhered to form the adhesive layers 131, 132 so that the open cavity OC of the piezoelectric layer 120 is closed to form the enclosed space C. The first adhesive layer 131 has a thickness range from 0.3□ to 10□, and may have a stable bonding strength within this thickness range, which is also advantageous from a manufacturing cost perspective. The thickness of the second adhesive layer 132 may be smaller than the thickness of the first adhesive layer 131.

In another embodiment, sub-adhesive layers are formed on a first surface of the piezoelectric layer 120 and a first surface of the second support substrate 110, respectively, and the first sub-adhesive layer formed on a first surface of the piezoelectric layer 120 and the second sub-adhesive layer formed on a first surface of the trap-rich layer 160 may be activated by irradiating a neutralizing beam on the first sub-adhesive layer and the second sub-adhesive layer. Then, by directly contacting the activated first sub-adhesive layer and the activated second sub-adhesive layer, and applying pressure, the adhesive layers 131, 132 may be obtained. An amorphous layer may be formed between the activated first sub-adhesive layer and the activated second sub-adhesive layer. Further, by introducing oxygen gas, the voltage force and oxygen partial pressure of the atmosphere in the chamber may be changed by changing the amount of oxygen gas introduced, and the oxygen ratio X of the first sub-adhesive layer and the second sub-adhesive layer may be adjusted thereby.

Subsequently, as shown in FIG. 4D, the first support substrate SS2 and dielectric layer SS1 may be removed to expose the other surface S4 of the piezoelectric layer 120 opposite the first surface S3 of the piezoelectric layer 120 in contact with the adhesive layers 131, 132. The first support substrate SS2 and the dielectric layer SS1 may be removed via a polishing process or an etching process. Subsequently, the IDT electrodes 140 and reflectors 151, 152 may be formed on the other surface S4 of the exposed piezoelectric layer 120, as shown in FIG. 4E.

Unlike the prior art, which, as described above, forms a sacrificial layer corresponding to the cavity on a support substrate, bonds the support substrate and the piezoelectric substrate, and then removes the sacrificial layer of the support substrate through an etching hole to form the cavity, the manufacturing method of the elastic wave device of the present invention does not require a complex and precise process of forming an etching hole and removing the sacrificial layer corresponding to the cavity through the etching hole, but simply bonds the support substrate and the piezoelectric substrate having the cavity to form the elastic wave device.

In addition, when the bonding process using the bonding material is carried out in a vacuum state, the cavity may be kept in a vacuum state, and no impurities or foreign substances exist in the vacuum state. Thus, by keeping the cavity in a vacuum state, the performance degradation of the piezoelectric layer caused by impurities or foreign substances may be improved.

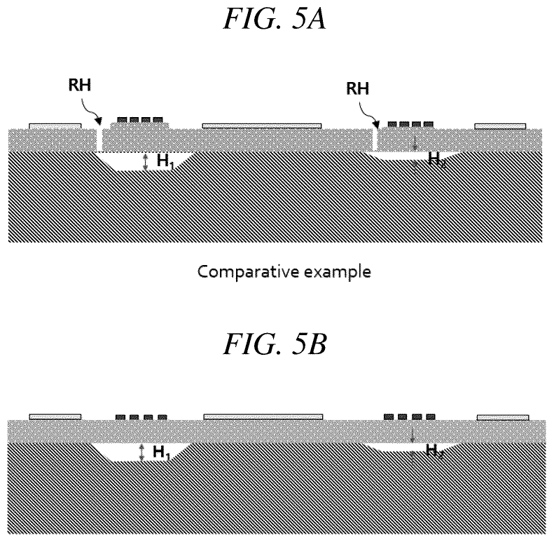

FIGS. 5A and 5B are drawings to illustrate the effect of a manufacturing method of an elastic wave element according to an embodiment of the present invention.

Referring to FIG. 5A, conventionally, to form the cavity, a sacrificial layer is formed on the support substrate, and then a piezoelectric layer is formed on the surface where the sacrificial layer is formed, so that the piezoelectric layer is not flat and has a protruding region due to the sacrificial layer. After forming an etching hole (RH), an etching gas or an etching solution may be injected into the etching hole to remove the sacrificial layer to form a cavity defined as a closed space. This conventional method requires a complex and precise etching process to remove the sacrificial layer through the etching hole RH.

Furthermore, in order to form an elastic wave element operating at a plurality of different resonant frequencies on the support substrate, a plurality of different sacrificial layers corresponding to the different resonant frequencies should be formed. For example, FIG. 5A illustrates an example of an elastic wave element operating at two different resonant frequencies, but the present disclosure is not limited thereto. Specifically, in FIG. 5A, when the height of the sacrificial layer is H₁ and H₂ smaller than H₁, the size of the protruding portions of the piezoelectric layer may also be different. To remove these protrusions, a separate polishing process is required, and the polishing process makes it difficult to achieve the thickness of the piezoelectric layer corresponding to the desired resonant frequencies. In addition, it is difficult to maintain the cavity in a vacuum state due to the etch holes (RH) described above.

On the other hand, as shown in FIG. 5B, in the present invention, no protrusions are formed on the piezoelectric layer through a simple process of bonding the piezoelectric substrate and the support substrate on which the cavity is formed using an adhesive layer, so a flattening process to remove the protrusions is unnecessary. In addition, the manufacturing process of the present invention does not require the formation of etch holes, so the cavity may be kept in a vacuum state.

This description discloses preferred embodiments of the present invention, and although certain terms are used, they are used in a general sense only to facilitate the description and understanding of the invention and are not intended to limit the scope of the invention. In addition to the embodiments disclosed herein, other modifications based on the technical ideas of the present invention are possible, as will be apparent to those of ordinary skill in the art to which the present invention belongs. A person having ordinary knowledge in the art will recognize that the elastic wave device and the method of manufacturing the elastic wave device according to the embodiments described with reference to FIGS. 1A to 5B may be substituted, altered, and modified in various ways without departing from the technical idea of the invention. Therefore, the scope of the invention is not to be defined by the embodiments described, but by the technical idea recited in the patent claims.

1. An elastic wave device, comprising:
a piezoelectric substrate having a first surface and a second surface;
a support substrate having a third surface adjacent or in contact with the first surface of the piezoelectric substrate to form a cavity defined by a space;
a first adhesive layer disposed between the support substrate and the piezoelectric substrate, forming a bonding interface to join the first surface of the support substrate and the third surface of the piezoelectric substrate;
a second adhesive layer formed on at least one of the third surface of the support substrate and the first surface of the piezoelectric substrate, which are surfaces where the bonding interface is not formed, the second adhesive layer being exposed within the cavity; and
an IDT electrode formed on the second surface of the piezoelectric substrate, and
wherein a thickness of the first adhesive layer is greater than a thickness of the second adhesive layer.

2. The device of claim 1, wherein the first adhesive layer and the second adhesive layer comprise an inorganic material, and the inorganic material comprises a ceramic material or a metallic material, and the inorganic material comprises a metal selected from the group of elements of Al, Si, Ti, V, Cr, Fe, Co, Ni, Cu, Zn, Ga, Ge, Zr, Nb, Mo, Ru, Rh, Pd, Ag, In, Sn, Hf, Ta, Pt, Au, W, or an alloy comprising at least one element selected from the group of elements, or an oxide thereof.

3. The device of claim 1, wherein the second adhesive layer does not have chemical bonds formed by atomic diffusion or atomic rearrangement, and has a structure identical to the shape of the cavity.

4. The device of claim 1, wherein the first adhesive layer comprises:
a first sub-adhesive layer deposited on one surface of the piezoelectric substrate and comprising a first metal atomic layer or a first ceramic atomic layer;
a second sub-adhesive layer deposited on one surface of the support substrate and comprising a second metal atomic layer or a second ceramic atomic layer; and
a bonding interface layer having chemical bonds formed by atomic diffusion or atomic rearrangement between the first sub-adhesive layer and the second sub-adhesive layer.

5. The device of claim 1, further comprising:
a trap rich layer on all or part of the third surface of the support substrate, and
wherein the trap-rich layer is disposed between the support substrate and the piezoelectric substrate, and the trap-rich layer is formed by at least one of polycrystalline silicon, amorphous silicon, or porous silicon.

6. The device of claim 1, wherein the piezoelectric substrate has a thickness ranging from 10□ to 500□.

7. The device of claim 1, wherein the second adhesive layer has a thickness ranging from 0.3□ to 10□ thickness, and the first adhesive layer has a thickness ranging from 1.2 times to 2.0 times the thickness of the second adhesive layer.

8. The device of claim 1, wherein the piezoelectric substrate comprises any one of lithium niobate (LiNbO₃), lithium tantalate, lanthanum gallium silicate, gallium nitride, or aluminum nitride, zinc oxide, or lead zirconate Titanate (PZT).

9. The device of claim 1, wherein the IDT electrode comprises aluminum (Al), copper (Cu), platinum (Pt), gold (Au), silver (Ag), titanium (Ti), nickel (Ni), chromium (Cr), molybdenum (Mo), tungsten (W), or an alloy based on any one of these metals.

10. The device of claim 1, wherein the support substrate is composed of any one of silicon (Si), glass, silicon carbide (SiC), and sapphire.

11. A method of manufacturing an elastic wave device, comprising
preparing a first support substrate having a first surface, and a piezoelectric layer formed on the first surface;
preparing a second support substrate having a second surface and having an open cavity on the second surface;
forming an atomic layer on an exposed surface of the piezoelectric layer formed on the first surface of the first support substrate and on the second surface of the second support substrate, respectively;
pressing the exposed surface of the piezoelectric layer against a second surface of the second support substrate to form an adhesive layer so that the open cavity of the second support substrate is closed to form a space;
removing the first support substrate so that the other surface opposite to the exposed surface of the piezoelectric layer is exposed; and
forming an IDT electrode on the other surface of the exposed piezoelectric layer.

12. The method of claim 11, wherein forming an atomic layer on the exposed surface of the piezoelectric layer formed on the first surface of the first support substrate and on the second surface of the second support substrate, respectively, comprises depositing an inorganic material on at least one of the exposed surface of the piezoelectric layer and the second surface of the second support substrate.

13. The method of claim 11, wherein pressing the exposed surface of the piezoelectric layer against the second surface of the second support substrate to form an adhesive layer so that the open cavity of the second support substrate is closed to form a space comprises forming a bonding interface layer through atomic diffusion between the first atomic layer and the second atomic layer.

14. The method of claim 11, wherein the step of forming the atomic layer and the step of forming the adhesive layer by closely contacting the exposed surface of the piezoelectric layer with a second surface of the second support substrate are performed under vacuum.

15. The method of claim 11, wherein the step of preparing the second support substrate comprises the step of forming a trap rich layer on all or a portion of the second surface of the second support substrate.

16. The method of claim 11, wherein the step of preparing the first support substrate further comprises the step of forming a dielectric layer between the first support substrate and the piezoelectric layer.

17. The method of claim 11, wherein the open cavity of the second support substrate is closed and the space formed is under vacuum.

18. The method of claim 11, further comprising:
oxidizing the atomic layer.
